(19) United States
(12) Patent Application Publication
(10) Pub. No.: US 2024/0055226 A1
(43) Pub. Date: Feb. 15, 2024

(54) INDUCTIVELY COUPLED PLASMA ETCHING APPARATUS, AND INDUCTIVELY COUPLED PLASMA ETCHING METHOD USING SAME

(71) Applicant: KOREA UNIVERSITY RESEARCH AND BUSINESS FOUNDATION, SEJONG CAMPUS, Sejong-si (KR)

(72) Inventors: Kwang Ho KWON, Daejeon (KR); No Min LIM, Sejong (KR); Byung Jun LEE, Ansan-si (KR)

(73) Assignee: KOREA UNIVERSITY RESEARCH AND BUSINESS FOUNDATION, SEJONG CAMPUS, Sejong-si (KR)

(21) Appl. No.: 18/487,581

(22) Filed: Oct. 16, 2023

Related U.S. Application Data
(63) Continuation of application No. PCT/KR2022/005342, filed on Apr. 13, 2022.

(30) Foreign Application Priority Data
Apr. 16, 2021 (KR) 10-2021-0049643
Jul. 7, 2021 (KR) 10-2021-0088952

(51) Int. Cl. H01J 37/32; H01L 21/3065

(52) U.S. Cl. CPC H01J 37/3211; H01J 37/32568; H01J 37/32449; H01L 21/3065; H01J 2237/334

(57) ABSTRACT

Provided is an inductively coupled plasma etching apparatus comprising: a reaction chamber having an inner space to which a gas source is provided; an upper coil part for inducing an electric field into the inner space of the reaction chamber and configured to form an inductively coupled plasma from the gas source by the electric field; a mounting part which faces the upper coil part and on which an object to be etched by the inductively coupled plasma is disposed; and a lower electrode part provided on the lower side of the mounting part to induce at least any one of ions and neutral active species constituting the inductively coupled plasma and involved in etching toward the object to be etched disposed on the mounting part, wherein the frequency of the lower electrode part is lower than the frequency of the upper coil part. In addition, provided is a method in which power of a lower frequency than the frequency applied to an upper electrode is applied to a lower electrode so that an object to be etched, which has been patterned with a mask material, is etched vertically using an inductively coupled plasma apparatus.

### TECHNICAL FIELD

The present invention relates to an inductively coupled plasma etching apparatus and an inductively coupled plasma etching method using the same, and more specifically, to an inductively coupled plasma etching apparatus capable of controlling ion energy while providing high ion energy, and an inductively coupled plasma etching method capable of vertically etching an insulating material patterned into a mask material using the same.

### BACKGROUND ART

Recently, as the degree of integration of semiconductor devices has increased and the capacity thereof has increased, the formation of high aspect ratio patterns in semiconductor devices has been required, and the formation of high aspect ratio patterns in such semiconductor devices has been rapidly increasing. In particular, a super high aspect ratio pattern such as a capacitor of a DRAM device and a channel hole of a vertical NAND flash memory device is being rapidly formed.

Meanwhile, as the formation of high aspect ratio patterns of a semiconductor device increases, etching loading such as a decrease in an etching rate and the verticality of an etched section also increases rapidly.

In order to solve the above-described etching loading in forming a high aspect ratio pattern of a semiconductor device, high energy ions generated from an etching gas are required to be supplied to a bottom surface of a pattern of, for example, a contact hole or a via hole.

In particular, in high aspect ratio contact (HARC) etching and via hole etching, a capacitively coupled plasma (CCP) etching apparatus capable of forming a plasma gas using a high radio frequency (RF) power generator is used.

However, the capacitively coupled plasma etching apparatus has a low gas ionization rate, and is difficult to control ion energy. Further, in order to allow ions to reach the etched bottom surface, a high-output power supply system is used for a lower electrode.

Meanwhile, in order to improve disadvantages such as a low ionization rate of a capacitively coupled plasma etching apparatus, an inductively coupled plasma (ICP) etching process is used in a semiconductor etching process.

The inductively coupled plasma etching apparatus may form a high-density plasma that is 10 times higher than that of the capacitively coupled plasma etching apparatus, and may have a high density of ions and neutral active species. In addition, since a mean free path of ions in the plasma is large due to a low process pressure, it is easy to obtain a vertical etch cross-section, and due to this advantage, it is considered an essential technique in the etching process for forming a pattern having a size of several nm. Therefore, most of the etching processes for manufacturing a semiconductor device are performed using an inductively coupled plasma.

However, although the etching process of the HARC pattern has a high specific gravity enough to occupy about 50% or more of the etching process of the semiconductor device, it is impossible to etch the insulating film patterned with a mask material by using the conventional inductively coupled plasma etching apparatus. This is because, when the sample is etched by the inductively coupled plasma, sufficient ions formed in the plasma may not reach the bottom surface of the sample. Due to such disadvantages of the inductively coupled plasma, an etching process has been entirely performed using the capacitively coupled plasma in the semiconductor process. However, the conventional capacitively coupled plasma etching apparatus has a problem in that the mean free path is small due to high process pressure, and as a result, it is difficult to form a vertical cross-section. In addition, in order to etch a HARC pattern, very large bias power is used, which causes a large capacity of the power system and causes an arcing phenomenon (electrical discharge caused by conversion of gas between two different electrodes into a current conducting medium) in a chamber.

Accordingly, in order to solve the above-described problems of capacitively coupled plasma, it is important to develop a HARC etching process by applying an inductively coupled plasma technology in which the plasma is easily formed at a low pressure, and as a result, a vertical etch cross-section is easily formed because of the large mean free path.

Meanwhile, in the method for etching the object to be etched using the conventional plasma etching apparatus, a fluorocarbon-based or inorganic fluoride-based perfluorocarbon (PFC)-based etching gas such as tetrafluoromethane (CF₄), fluoroform (CHF₃), perfluorobutene (C₄F₈), sulfur hexafluoride (SF₆), nitron fluorine three (NF₃), and perfluoropropane (C₃F₈) is being used. However, the conventional PFC-based etching gas has a high global warming potential (GWP), which may cause global environmental problems such as global warming.

In addition, when the object to be etched is etched using the conventional PFC-based etching gas, ion density is high, and thus, when the object to be etched is a dielectric thin film such as SiOC, the dielectric thin film may be damaged and permittivity thereof may be changed.

Accordingly, in order to solve the above-described problems, it is necessary to apply a liquid etching source having a low global warming potential and capable of replacing the conventional PFC-based etching gas.

### DISCLOSURE

### Technical Problem

One technical problem to be solved by the present invention is to provide an inductively coupled plasma etching apparatus which provides high ion energy to be applied to a HARC or an etching process of a high aspect ratio via hole, and an inductively coupled plasma etching method using the same.

Another technical problem to be solved by the present invention is to provide a method for etching an insulating film having a pattern with a high aspect ratio using an inductively coupled plasma etching apparatus, and a method for etching an object to be etched.

Still another technical problem to be solved by the present invention is to provide an inductively coupled plasma etching apparatus which controls ion energy and an inductively coupled plasma etching method using the same.

Still another technical problem to be solved by the present invention is to provide an inductively coupled plasma etching apparatus using a liquid source having low ion density and an inductively coupled plasma etching method using the same.

The technical problems to be solved by the present invention are not limited to those described above.

### Technical Solution

In order to solve the technical problems, the present invention provides an inductively coupled plasma etching apparatus.

According to one embodiment, an inductively coupled plasma etching apparatus includes: a reaction chamber having an inner space to which a gas source is provided; an upper coil part configured to induce an electric field into the inner space of the reaction chamber and form an inductively coupled plasma from the gas source by the electric field; a mounting part which faces the upper coil part and on which an object to be etched by the inductively coupled plasma is disposed; and a lower electrode part provided on a lower side of the mounting part to induce at least any one of ions and neutral active species forming the inductively coupled plasma and involved in etching toward the object to be etched disposed on the mounting part, wherein a frequency of the lower electrode part may be lower than a frequency of the upper coil part.

According to one embodiment, the inductively coupled plasma etching apparatus may further include: a radio frequency power supply source for applying radio frequency power to the upper coil part; a low frequency power supply source for applying frequency power of several hundreds of kHz to MHz, for example, low frequency power of 400 kHz or 2 MHz to the lower electrode part; a radio frequency power matching part provided in a power supply line between the radio frequency power supply source and the upper coil part; and, a low frequency power matching part provided in a power supply line between the low frequency power supply source and the lower electrode part, wherein the low frequency power supply source may apply the low frequency power to the lower electrode part as a pulse.

According to one embodiment, the inductively coupled plasma etching apparatus may further include a gas supply unit configured to provide the gas source into the inner space of the reaction chamber, wherein the gas supply unit may include: a liquid source storage part configured to store a liquid source which is in a liquid state at normal temperature; a heating part configured to surround the liquid source storage part and heat the liquid source stored in the liquid source storage part to form the gas source from the liquid source; a carrier gas for carrying the gas source; a flow rate adjustment part configured to adjust a flow rate of at least one of the gas source and the carrier gas; and a gas source supply part configured to supply the gas source carried by the carrier gas into the inner space of the reaction chamber.

According to one embodiment, the gas supply unit may further include a gas source storage part configured to store a gas source which is in a gaseous state at normal temperature.

According to one embodiment, the inductively coupled plasma etching apparatus may further include: a dielectric plate disposed under the upper coil part; and a pressure adjustment part configured to adjust a pressure of the inner space of the reaction chamber.

According to one embodiment, a pattern, which is formed on the object to be etched as the object is etched, may have a critical dimension (CD) ratio between a top layer, which is defined as a layer toward the upper coil part, and a bottom layer, which is defined as a layer toward the lower electrode part, in a range of 0.95 to 1, and may be vertically etched at a pattern size of micrometer or less in a direction from the top layer to the bottom layer.

In order to solve the technical problems, the present invention provides an inductively coupled plasma etching method.

According to one embodiment, an inductively coupled plasma etching method includes: disposing an object to be etched on a lower side of an inner space of a reaction chamber; providing a gas source into the inner space of the reaction chamber; inducing an electric field into the inner space of the reaction chamber by an upper coil part of the inner space of the reaction chamber, and forming an inductively coupled plasma from the gas source by the electric field; and etching the object to be etched by inducing at least one of ions and neutral active species, which form the inductively coupled plasma and are involved in etching, toward the object to be etched by a lower electrode part facing the upper coil part, wherein a frequency of the lower electrode part may be lower than a frequency of the upper coil part.

According to one embodiment, the frequency of the lower electrode may be lower than the frequency of the upper coil part, and may be in a range of not less than 400 kHz and less than 13.56 MHz.

According to one embodiment, the etching of the object to be etched may include adjusting ion energy by applying low frequency power to the lower electrode part as a pulse.

According to one embodiment, the etching of the object to be etched may include adjusting a duty ratio of bias power in order to adjust a voltage applied to a sample located on the lower electrode.

According to one embodiment, the providing of the gas source may include: storing a liquid source which is in a liquid state at normal temperature; heating the stored liquid source to form the gas source from the liquid source; providing a carrier gas for carrying the gas source to the gas source; and supplying the gas source carried by the carrier gas into the inner space of the reaction chamber, and in at least one of providing of the carrier gas and supplying of the gas source into the reaction chamber, a flow rate of at least one of the gas source and the carrier gas may be adjusted.

### Advantageous Effects

According to the embodiment of the present invention, it is possible to provide an inductively coupled plasma etching apparatus including: a reaction chamber having an inner space to which a gas source is provided; an upper coil part configured to induce an electric field into the inner space of the reaction chamber and form an inductively coupled plasma from the gas source by the electric field; a mounting part which faces the upper coil part and on which an object to be etched by the inductively coupled plasma is disposed; and a lower electrode part provided on a lower side of the mounting part to induce at least any one of ions and neutral active species forming the inductively coupled plasma and involved in etching toward the object to be etched disposed on the mounting part, in which a frequency of the lower electrode part is lower than a frequency of the upper coil part.

Accordingly, since the radio frequency power is applied to the upper coil part and the low frequency power is applied to the lower electrode part, a larger voltage may be induced with the same power compared to a case in which the radio frequency power is applied. As the low frequency pulse power is applied, the critical dimension (CD) of the pattern formed by etching the object to be etched hardly changes according to an etching depth.

In addition, by applying a pulse to the low frequency power source, the ion energy reaching the sample may be adjusted by adjusting the voltage applied to the sample.

As a result, it is possible to perform a HARC process using the inductively coupled plasma, which has been conventionally performed using only a CCP etching apparatus, and to provide a method for etching a pattern having a high aspect ratio and a method for etching an object to be etched, with lower power than the CCP.

In addition, according to one embodiment of the present invention, the gas source is obtained by converting a liquid source having a lower ion density than a conventional gas source, and thus the gas source may safely etch the object to be etched while minimizing damage to the object to be etched.

Meanwhile, the gas source is an eco-friendly gas source obtained by converting the liquid source having a lower global warming potential than the conventional gas source, thereby minimizing global environmental problems such as global warming.

### DESCRIPTION OF DRAWINGS

FIG. 1 is a view for explaining an inductively coupled plasma etching apparatus according to an embodiment of the present invention.

FIGS. 2 and 3 are views for explaining an inductively coupled plasma etching method according to an embodiment of the present invention.

FIGS. 4 to 12 are views for explaining experimental examples of the present invention.

### MODE FOR INVENTION

Hereinafter, preferred embodiments of the present invention will be described in detail with reference to the accompanying drawings. However, the present invention may be embodied in different forms and should not be construed as limited to the embodiments set forth herein. Rather, the embodiments introduced herein are provided so that disclosed contents will be thorough and complete, and will fully convey the scope of the present invention to those skilled in the art.

In the present specification, it will be understood that when an element is referred to as being “on” another element, it can be formed directly on the other element or intervening elements may be present. In the drawings, the shapes and the thicknesses of regions are exaggerated for clarity.

In addition, it will be also understood that although the terms first, second, third, etc. may be used herein to describe various elements, these elements should not be limited by these terms. These terms are only used to distinguish one element from another element. Thus, a first element in some embodiments may be termed a second element in other embodiments without departing from the teachings of the present invention. Embodiments explained and illustrated herein include their complementary counterparts. As used herein, the term “and/or” includes any and all combinations of one or more of the associated listed elements.

The singular expression also includes the plural meaning as long as it does not differently mean in the context. In addition, the terms “comprise”, “have” etc., of the description are used to indicate that there are features, numbers, steps, elements, or combination thereof, and they should not exclude the possibilities of combination or addition of one or more features, numbers, operations, elements, or a combination thereof. Furthermore, it will be understood that when an element is referred to as being “connected” or “coupled” to another element, it may be directly connected or coupled to the other element or intervening elements may be present.

In addition, the terms such as “unit”, “ . . . er/or”, “module”, and the like described herein mean a unit for processing at least one function or operation, and may be implemented by hardware, software, or a combination of hardware and software.

In addition, when detailed descriptions of related known functions or constitutions are considered to unnecessarily cloud the gist of the present invention in describing the present invention below, the detailed descriptions will not be included.

Hereinafter, an inductively coupled plasma etching apparatus according to an embodiment of the present invention will be described with reference to the drawings.

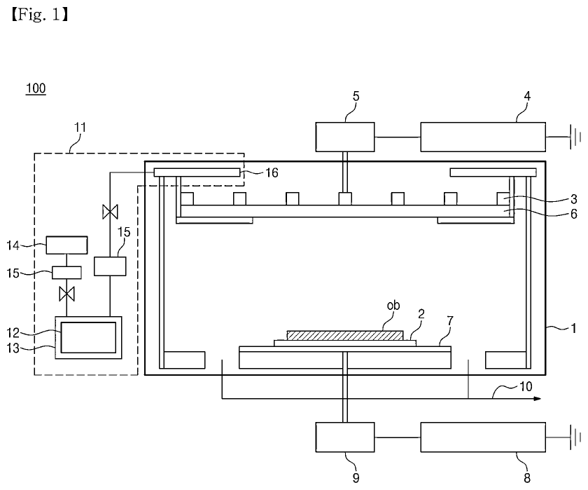

FIG. 1 is a view for explaining an inductively coupled plasma etching apparatus according to an embodiment of the present invention.

According to the inductively coupled plasma etching apparatus according to one embodiment of the present invention, critical dimension (CD) values at top, mid, and bottom layers of a pattern formed by etching an object to be etched may be uniform.

To this end, referring to FIG. 1, an inductively coupled plasma etching apparatus 100 may include at least one of a reaction chamber 1, a mounting part 2, an upper coil part 3, a radio frequency power supply source 4, a radio frequency power matching part 5, a dielectric plate 6, a lower electrode part 7, a low frequency power supply source 8, a low frequency power matching part 9, and a pressure adjustment part 10.

Hereinafter, each configuration will be described.

The reaction chamber 1 may have an inner space in which a gas source is provided, as illustrated in FIG. 1.

According to one embodiment, the gas source may be an eco-friendly etching source that exists as a liquid source (liquid-perfluorocarbon (L-PFC)), which is a liquid state at normal temperature, and is converted into a gas source by being heated.

Alternatively, according to one embodiment, the gas source may be a gas source which is in a gaseous state at normal temperature. For example, the gas source may be a perfluorocarbon (PFC) gas that has been used.

This will be described with reference to the description of a gas supply unit 11 to be described below.

In the inner space of the reaction chamber 1, at least one of the mounting part 2, the upper coil part 3, the dielectric plate 6, the lower electrode part 7, and the gas source supply part 16, which will be described below, may be disposed.

Meanwhile, a pressure in the inner space of the reaction chamber 1 may be adjusted by a pressure adjustment part 10 to be described below. For example, the inner space of the reaction chamber 1 may be adjusted to a vacuum state.

Accordingly, as illustrated in FIG. 1, in the inner space of the reaction chamber 1, an object to be etched ob, which is disposed on the mounting part 2, may be etched, for example, may be etched into a contact hole by an inductively coupled plasma formed from the gas source by the upper coil part 3.

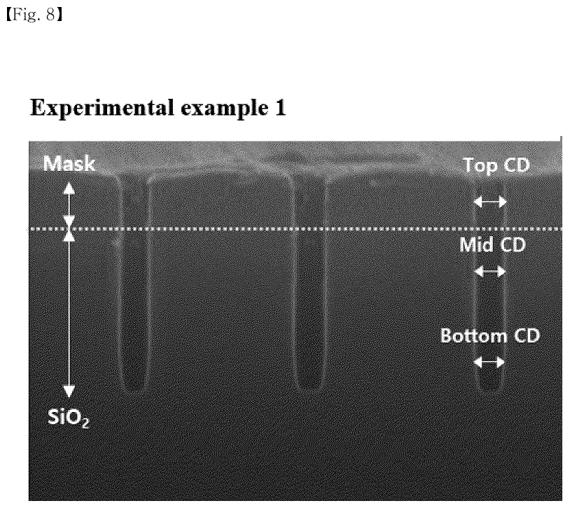

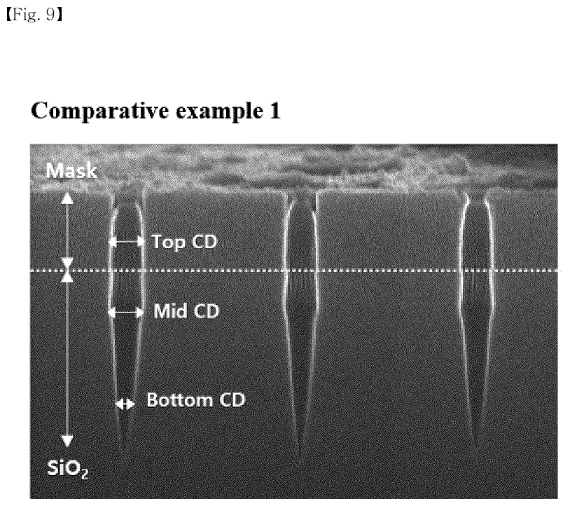

As illustrated in FIG. 1, the object to be etched ob may be disposed on the mounting part 2. In this case, the expression “object to be etched ob” may mean an etching object that is etched by the inductively coupled plasma formed from the gas source by the upper coil part 3 to be described below. More specifically, the object to be etched ob according to one embodiment of the present invention may be a dielectric thin film or a porous thin film made of SiO₂, SiOC, and SiO₂, and the dielectric thin film or porous thin film may be used as an inter metal dielectric (IMD) and an inter layer dielectric (ILD) (meanwhile, when the object to be etched ob is made of SiO₂, a masking material may be poly-Si and amorphous carbon layer, see FIGS. 8 and 9).

When a vapor phase source having a high ion density is used for etching as in the related art, damage such as a change in the dielectric constant of the thin film may occur.

Accordingly, the present invention provides a method for safely etching the object to be etched ob while minimizing damage to the object to be etched ob. This will be described below with reference to the description of the gas supply unit 11.

Meanwhile, as illustrated in FIG. 1, the mounting part 2 may be disposed in the inner space of the reaction chamber 1, and may be provided to face the upper coil part 3 to be described below. Meanwhile, the lower electrode part 7 to be described below may be provided on a lower side of the mounting part 2.

This is to induce at least one of ions and neutral active species, which are involved in etching of the inductively coupled plasma formed from the gas source by the upper coil part 3, toward the object to be etched ob disposed on the mounting part 2 by the lower electrode part 7.

Accordingly, the object to be etched ob disposed in the mounting part 2 may be etched to form a pattern on the object to be etched ob. In this case, the pattern may mean various patterns such as contact holes and lines. Meanwhile, the object to be etched ob may be a dielectric thin film or a porous thin film made of SiO₂, SiOC, and SiO₂, and the dielectric thin film or porous thin film may be used as an inter metal dielectric (IMD) and an inter layer dielectric (ILD). This will be described below with reference to the description of the lower electrode part 7.

The upper coil part 3 may induce an electric field into the inner space of the reaction chamber 1.

To this end, the upper coil part 3 may be electrically connected to a radio frequency power supply source 4 to be described below to receive radio frequency power. More specifically, the upper coil part 3 may receive radio frequency power having a frequency higher than that of the lower electrode part 7 to be described below.

Meanwhile, according to one embodiment, the upper coil part 3 may be provided on an upper side of the inner space of the reaction chamber 1 as illustrated in FIG. 1. The term “upper side” used herein may mean one side of the inner space of the reaction chamber 1, which faces the lower electrode part 7 to be described below.

Meanwhile, the gas source supply part 16 to be described below may be disposed adjacent to the upper coil part 3. The gas source supply part 16, which will be described below, supplies the gas source into the inner space of the reaction chamber 1, so that the inductively coupled plasma may be formed from the gas source through the electric field that is induced into the inner space of the reaction chamber 1 by the upper coil part 3.

The radio frequency power supply source 4 may apply radio frequency power to the upper coil part 3. More specifically, the radio frequency power supply source 4 may apply radio frequency power having a frequency higher than that of the lower electrode part 7 to be described below to the upper coil part 3. For example, the radio frequency power applied from the radio frequency power supply source 4 to the upper coil part 3 may be tens of MHz, for example, 13.56 MHz or an integer multiple thereof.

To this end, the radio frequency power supply source 4 may be electrically connected to the upper coil part 3 as described above.

According to one embodiment, the radio frequency power supply source 4 may be electrically connected to the upper coil part 3, and may be provided in an outer space of the reaction chamber 1 as illustrated in FIG. 1.

In this case, as illustrated in FIG. 1, the radio frequency power matching part 5 may be provided in a power supply line between the radio frequency power supply source 4 and the upper coil part 3.

Accordingly, the radio frequency power matching part 5 may minimize an impedance difference between an output terminal of the radio frequency power supply source 4 and an input terminal of the upper coil part 3, thereby matching impedance.

According to one embodiment, the radio frequency power matching part 5 may be provided in a power supply line between the radio frequency power supply source 4 and the upper coil part 3, and may be provided in the outer space of the reaction chamber 1 together with the radio frequency power supply source 4 as illustrated in FIG. 1.

The dielectric plate 6 may maximize transfer efficiency by blocking the inner space of the reaction chamber 1 from the outside and transferring the electric field induced by the upper coil part 3 to the gas source.

This is because a state in which the electric field induced by the upper coil part 3 is transferred to the gas source, that is, a state in which radio frequency (RF) power is transferred to the gas source is changed according to the permittivity of the dielectric constituting the dielectric plate 6. In other words, the dielectric plate 6 may help to form the inductively coupled plasma in the optimal state by transferring the frequency power to the gas source in the inner space of the reaction chamber 1.

To this end, as illustrated in FIG. 1, the dielectric plate 6 may be disposed beneath the upper coil part 3 and may be made of quartz.

The lower electrode part 7 may induce at least one of ions and neutral active species forming the inductively coupled plasma toward the object to be etched ob disposed on the mounting part 2. The ions and neutral active species used herein may be involved in etching of the object to be etched ob.

More specifically, ions, specifically, cations in the inductively coupled plasma may be induced to be accelerated toward the object to be etched ob, which is disposed on the mounting part 2 provided on the lower electrode part 7, due to bias applied across the lower electrode part 7.

Accordingly, the object to be etched ob may be etched by the cations.

Meanwhile, the neutral active species in the inductively coupled plasma may be induced toward the object to be etched ob and may be bonded to atoms on a surface of the object to be etched ob to form molecules having a strong volatility, and may be separated from the surface of the object to be etched ob.

Accordingly, the object to be etched ob may be etched by the neutral active species.

According to one embodiment of the present invention, a pattern, which is formed on the object to be etched ob as the object to be etched ob is etched, may have a constant critical dimension (CD) value between a top layer, a mid layer, and a bottom layer in a direction from the upper coil part 3 to the lower electrode part 7.

This means that, according to the embodiment of the present invention, it is possible to form a pattern in which an insulating film is vertically etched to a size of a micrometer or less using high ion energy provided through the inductively coupled plasma apparatus 100.

The “CD” used herein may mean a minimum line width in the pattern (see FIG. 8). In other words, the uniform CD ratio between the top layer, the mid layer, and the lower layer of the pattern may be an index indicating that the pattern is uniformly etched in the direction from the upper coil part 3 to the lower electrode part 7.

To this end, the lower electrode part 7 may be provided on a lower side of the mounting part 2 in the inner space of the reaction chamber 1 as illustrated in FIG. 1, and may be electrically connected to the low frequency power supply source 8 to be described below, thereby receiving low frequency power. More specifically, the lower electrode part 7 may receive low frequency power having a frequency lower than that of the upper coil part 3.

Accordingly, the inductively coupled plasma etching apparatus 100 according to the embodiment of the present invention may provide high ion energy in etching the object to be etched ob through the low frequency power.

Meanwhile, the lower electrode part 7 may receive the low frequency power from the low frequency power supply source 8 to be described below, and may receive the low frequency power as a pulse.

Accordingly, the inductively coupled plasma etching apparatus 100 according to the embodiment of the present invention may control ion energy in etching the object to be etched ob by the duty ratio of the low frequency pulse power and the pulse power.

In other words, according to the embodiment of the present invention, the radio frequency power is applied to the upper coil part 3 and the low frequency pulse power is applied to the lower electrode part 7, so that the CD ratio of the pattern formed by etching the object to be etched ob may be uniform as described above.

The low frequency power supply source 8 may apply low frequency power to the lower electrode part 7. More specifically, the low frequency power supply source 8 may apply radio frequency power having a frequency lower than that of the upper coil part 3 to the lower electrode part 7. For example, the low frequency power applied from the low frequency power supply source 8 to the lower electrode part 7 may be in a range of several hundreds of kHz to several MHz, for example, 400 kHz or 2 MHz.

Accordingly, as described above, high ion energy may be provided in the etching of the object to be etched ob through the low frequency power.

Meanwhile, the low frequency power supply source 8 may apply the low frequency power as a pulse in applying the low frequency power to the lower electrode part 7.

Accordingly, as described above, the ion energy may be controlled by the duty ratio of power or pulse power of the low frequency pulse power supply.

To this end, the low frequency power supply source 8 may be electrically connected to the lower electrode part 7.

According to one embodiment, the low frequency power supply source 8 may be electrically connected to the lower electrode part 7, and as illustrated in FIG. 1, may be provided in the outer space of the reaction chamber 1.

As illustrated in FIG. 1, the low frequency power matching part 9 may be provided in the power supply line between the low frequency power supply source 8 and the lower electrode part 7.

Accordingly, the low frequency power matching part 9 may minimize an impedance difference between the output terminal of the low frequency power supply source 8 and the input terminal of the lower electrode part 7, thereby matching impedance.

According to one embodiment, the low frequency power matching part 9 may be provided in the power supply line between the low frequency power supply source 8 and the lower electrode part 7, and as illustrated in FIG. 1, may be provided in the outer space of the reaction chamber 1 together with the low frequency power supply source 8 described above.

The pressure adjustment part 10 may control the pressure of the inner space of the reaction chamber 1. More specifically, the pressure adjustment part 10 may adjust the inner space of the reaction chamber 1 to a vacuum state.

Accordingly, it is possible to easily form the inductively coupled plasma from the gas source in the inner space of the reaction chamber 1.

According to one embodiment, the pressure adjustment part 10 may be a vacuum pump, for example, a turbo pump.

Meanwhile, even when a SiOC thin film is etched using the liquid gas source in the inductively coupled plasma etching apparatus 100 according to one embodiment of the present invention, it is possible to minimize etching damage in which the dielectric constant of the object to be etched is increased.

When the object to be etched ob is a SiO₂ porous thin film, it may include a plurality of pores. Accordingly, the object to be etched ob may have high brittleness.

When the object to be etched ob having high brittleness is etched using a plasma formed from a conventional vapor source, the object to be etched ob having high brittleness may be damaged. This is because the conventional vapor source has a high ion density, and when the object to be etched ob having high brittleness is etched by providing the conventional vapor source having a high ion density to the object to be etched ob having high brittleness, an excessive amount of ions is injected into the object to be etched ob having high brittleness.

However, according to the inductively coupled plasma etching apparatus 100 according to one embodiment of the present invention, the object to be etched ob having high brittleness may be safely etched using a liquid source having a low ion density compared to the conventional vapor source. Accordingly, damage to the object to be etched ob having high brittleness may be minimized.

Further, a fluorocarbon-based or inorganic fluoride-based perfluorocarbon (PFC)-based etching gas such as tetrafluoromethane (CF₄), fluoroform (CHF₃), perfluorobutene (C₄F₈), sulfur hexafluoride (SF₆), nitron fluorine three (NF₃), and perfluoropropane (C₃F₈), which are used in the method for etching the object to be etched using the conventional plasma etching apparatus, may have high global warming potential, which may cause global environmental problems such as global warming.

On the other hand, according to the inductively coupled plasma etching apparatus 100 according to one embodiment of the present invention, not only the conventional vapor source but also the eco-friendly gas source converted from the liquid source having a low global warming potential may be used, thereby minimizing global environmental problems such as global warming. For example, the liquid source according to one embodiment of the present invention may include at least one of decafluoropentane (C₅H₂F₁₀), tetrafluoropropene (C₃H₂F₄), Hexafluorobenzene (C₆F₆), and perfluoro-2-methyl-3-pentanone (C₆F₁₂O).

To this end, as illustrated in FIG. 1, the inductively coupled plasma etching apparatus 100 may further include the gas supply unit 11.

The gas supply unit 11 may provide the gas source into the inner space of the reaction chamber 1.

To this end, the gas supply unit 11 may include at least one of a liquid source storage part 12, a heating part 13, a carrier gas 14, a flow rate adjustment part 15, and a gas source supply part 16.

Hereinafter, each configuration will be described.

The liquid source storage part 12 may store a liquid source before the gas source is formed. This is to consider that the liquid source is a liquid phase at normal temperature. In other words, the liquid source exists in a liquid state while being stored in the liquid source storage part 12, and when the liquid source is heated by the heating part 13 to be described below, the liquid source may be formed as the gas source.

Meanwhile, as shown in the following <Table 1>, the liquid source stored in the liquid source storage part 12 may have a global warming potential (GWP) that is lower than that of the conventional gas source shown in <Table 2>.

TABLE 1

| Liquid Source of Present | |
|---|---|
| Invention | GWP |
| decafluoropentane (C₅H₂F₁₀) | 1,640 |
| tetrafluoropropene (C₃H₂F₄) | 1,350 |
| hexafluorobenzene (C₆F₆) | 7 |
| perfluoro-2-methyl-3- | 0.1 |
| pentanone (C₆F₁₂O) | |

TABLE 2

| Conventional Vapor source | GWP |
|---|---|
| tetrafluoromethane (CF₄) | 6,300 |
| fluoroform (CHF₃) | 12,100 |
| perfluorobutene (C₄F₈) | 8,700 |
| sulfur hexafluoride (SF₆) | 23,900 |
| hexafluoroethane (C₂F₆) | 12,500 |
| nitron Fluorine three (NF₃) | 8,000 |
| perfluoropropane (C₃F₈) | 7,000 |
| *carbon dioxide (CO₂) | 1 |

*reference

Accordingly, according to the embodiment of the present invention using the liquid source, a global environmental problem such as global warming may be minimized.

The heating part 13 may heat the liquid source stored in the liquid source storage part 12 to form the gas source.

To this end, the heating part 13 may be provided to surround the liquid source storage part 12, as illustrated in FIG. 1.

The carrier gas 14 may carry the gas source. More specifically, when the etching of the object to be etched ob starts in the inner space of the reaction chamber 1, the carrier gas 14 may carry the gas source to the gas source supply part 16 to be described below.

To this end, as illustrated in FIG. 1, the carrier gas 14 is disposed in a space separated from the liquid source storage part 12 and the heating part 13, so that before starting the etching of the object to be etched ob as described above, the carrier gas 14 may block the contact with the gas source, and when the etching of the object to be etched ob is started as described above, the carrier gas 14 makes contact with the gas source to carry the gas source to the gas source supply part 16 to be described below.

The contact between the carrier gas 14 and the gas source may be controlled by the flow rate adjustment part 15 to be described below.

The flow rate adjustment part 15 may adjust a flow rate of at least one of the gas source and the carrier gas.

To this end, as illustrated in FIG. 1, the flow rate adjustment part 15 may be provided in at least one of a carrier gas supply line between the carrier gas 14 and the heating part 13 and a gas source supply line between the heating part 13 and a gas source supply part 16 to be described below.

The gas source supply part 16 may supply the gas source carried by the carrier gas into the inner space of the reaction chamber 1.

To this end, as illustrated in FIG. 1, at least one side of the gas source supply part 16 may communicate with the inner space of the reaction chamber 1.

Meanwhile, as described above, the gas source supply part 16 may be disposed adjacent to the upper coil part 3. This takes into account that, as described above, the electric field is induced into the inner space of the reaction chamber 1 by the upper coil part 3, and inductively coupled plasma is formed from the gas source by the induced electric field.

Meanwhile, according to the embodiment of the present invention, the liquid gas source, which is used for etching the object to be etched ob in the inner space of the reaction chamber 1, may be collected and reused. Accordingly, it has economic advantages.

In addition, according to the embodiment of the present invention, the liquid source is a liquid phase at normal temperature, so that it has less risk of leakage compared to the conventional vapor source, is easily stored, and may prevent environmental pollution.

Meanwhile, the gas supply unit 11 may further include a gas source storage part (not illustrated).

The gas source storage part (not illustrated) may store a gas source which is in a gaseous state at normal temperature, for example, existing perfluorocarbon (PFC).

Accordingly, according to one embodiment of the present invention, the gas source, which is in a gaseous state at the normal temperature, stored in the gas source storage part may be provided through the gas supply unit 11.

Even in this case, the gas source stored in the gas source storage part may be provided to the inner space of the reaction chamber 1 through the carrier gas 14, the flow rate adjustment part 15, and the gas source supply part 16.

Hereinabove, the inductively coupled plasma etching apparatus according to the embodiment of the present invention has been described.

Hereinafter, an inductively coupled plasma etching method according to the embodiment of the present invention will be described.

In the inductively coupled plasma etching method according to the embodiment of the present invention, which will be described below, the description overlapping with the above-described embodiment and modified example may be omitted. However, although the overlapped description is omitted below, the above-described configurations are not included or excluded.

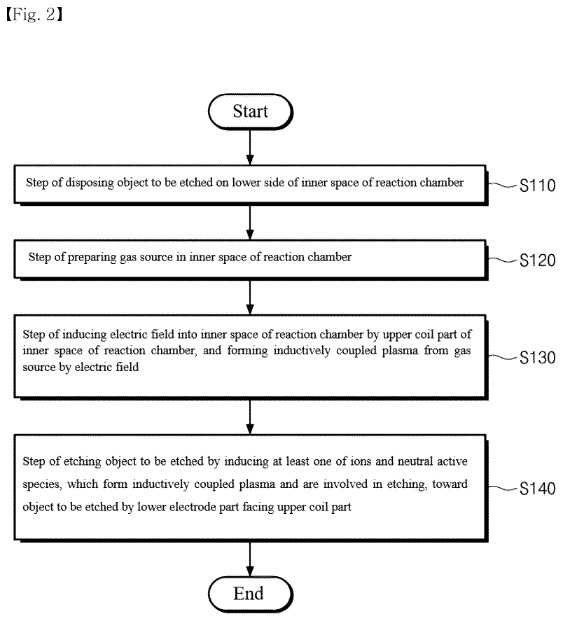

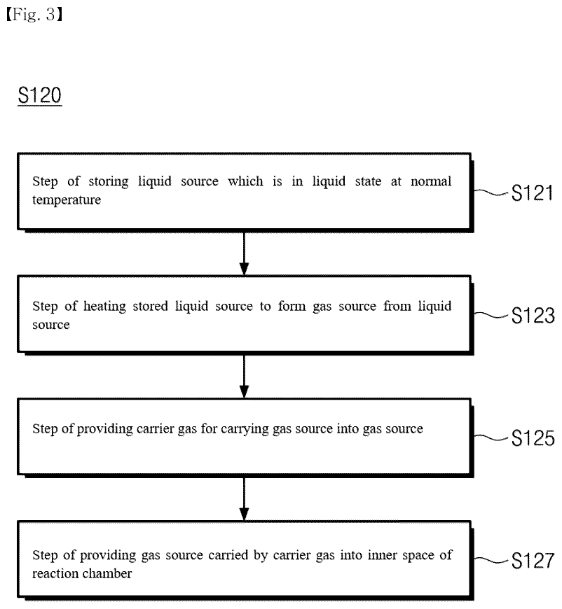

FIGS. 2 and 3 are views for explaining an inductively coupled plasma etching method according to an embodiment of the present invention.

Referring to FIG. 2, the inductively coupled plasma etching method may include at least one of: disposing an object to be etched on a lower side of an inner space of a reaction chamber (S110); providing a gas source into the inner space of the reaction chamber (S120); inducing an electric field into the inner space of the reaction chamber by an upper coil part of the inner space of the reaction chamber, and forming an inductively coupled plasma from the gas source by the electric field (S130); and etching the object to be etched by inducing at least one of ions and neutral active species, which form the inductively coupled plasma and are involved in etching, toward the object to be etched by a lower electrode part facing the upper coil part (S140).

Hereinafter, each step will be described.

Step S110

In step S110, the object to be etched ob may be disposed on a lower side of the inner space of the reaction chamber 1. More specifically, as illustrated in FIG. 1, the object to be etched ob may be disposed on the mounting part 2 on the lower side of the inner space of the reaction chamber 1.

Step S120

In step S120, a gas source may be provided to the inner space of the reaction chamber 1.

In this case, a pressure of the inner space of the reaction chamber 1 may be adjusted by the pressure adjustment part 10. More specifically, the pressure adjustment part 10 may adjust the inner space of the reaction chamber 1 to a vacuum state.

The present step may further Include a detailed step to provide the gas source to the inner space of the reaction chamber 1.

Referring to FIG. 3, the detailed step of providing of the gas source may include at least one of: storing a liquid source which is in a liquid state at normal temperature (S121); heating the stored liquid source to form the gas source from the liquid source (S123); providing a carrier gas for carrying the gas source to the gas source (S125); and supplying the gas source carried by the carrier gas into the inner space of the reaction chamber (S127).

Hereinafter, each step will be described.

Step S121

In step S121, a liquid source, which is in a liquid state at normal temperature, may be stored in the liquid source storage part 12. As described above, this is to consider that the liquid source is a liquid phase at normal temperature. In other words, the liquid source exists in a liquid state while being stored in the liquid source storage part 12, and when the liquid source is heated by the heating part 13 to be described below, the liquid source may be formed as the gas source.

Meanwhile, the liquid source stored in the liquid source storage part 12 may have a global warming potential (GWP) that is lower than that of the conventional vapor source, as described above with reference to <Table 1> and <Table 2>. Accordingly, in the present step, it is possible to minimize global environmental problems such as global warming by using the liquid source. IN this regard, refer to the above description of <Table 1> and <Table 2>.

Step S123

In step S123, the stored liquid source may be heated in the heating part 13 to form the gas source from the liquid source.

To this end, as described above, the heating part 13 may be provided to surround the liquid source storage part 12.

Step S125

In step S125, the carrier gas 14 for carrying the gas source may be provided to the gas source.

Accordingly, the carrier gas 14 may carry the gas source to the gas source supply part 16 in a step to be described below.

Step S127

In step S127, the gas source supply part 16 may supply the gas source carried by the carrier gas into the inner space of the reaction chamber 1.

To this end, as described above, at least one side of the gas source supply part 16 may communicate with the inner space of the reaction chamber 1.

Meanwhile, as described above, the gas source supply part 16 may be disposed adjacent to the upper coil part 3. This is because, as described above, the electric field is induced into the inner space of the reaction chamber 1 by the upper coil part 3, and inductively coupled plasma is formed from the gas source by the induced electric field.

Meanwhile, in at least one of steps S125 and S127, a flow rate of at least one of the gas source and the carrier gas may be adjusted.

Meanwhile, according to the embodiment of the present invention, in step S120, the gas source provided to the inner space of the reaction chamber 1 may be the existing perfluorocarbon (PFC) which is in a gaseous state at normal temperature.

Step S130

Referring back to FIG. 2, in step S130, an electric field may be induced into the inner space of the reaction chamber 1 by the upper coil part 3 of the inner space of the reaction chamber 1, and an inductively coupled plasma may be formed from the gas source by the electric field.

To this end, as described above, the upper coil part 3 may be electrically connected to the radio frequency power supply source 4 to receive radio frequency power. More specifically, the upper coil part 3 may receive radio frequency power having a frequency higher than that of the lower electrode part 7 to be described below.

To this end, the radio frequency power supply source 4 may be electrically connected to the upper coil part 3 as described above.

In this case, the radio frequency power matching part 5 may be provided in a power supply line between the radio frequency power supply source 4 and the upper coil part 3, as described above.

Accordingly, the radio frequency power matching part 5 may match impedance by minimizing an impedance difference between an output terminal of the radio frequency power supply source 4 and an input terminal of the upper coil part 3.

Step S140

In step S140, the object to be etched ob may be etched by inducing at least one of ions and neutral active species, which form inductively coupled plasma and are involved in etching, toward the object to be etched ob by the lower electrode part 7 facing the upper coil part 3.

More specifically, ions, specifically, cations in the inductively coupled plasma may be induced to be accelerated toward the object to be etched ob, which is disposed on the mounting part 2 on the lower electrode part 7 due to bias applied across the lower electrode part 7.

Accordingly, the object to be etched ob may be etched by the cations.

Meanwhile, the neutral active species in the inductively coupled plasma may be induced toward the object to be etched ob and bonded to atoms on a surface of the object to be etched ob to form molecules having strong volatility, and may be separated from the surface of the object to be etched ob.

Accordingly, the object to be etched ob may be etched by the neutral active species.

Meanwhile, in the present step, the pattern, which is formed on the object to be etched ob as the object to be etched ob is etched, may have a uniform critical dimension (CD) value between a top layer, a mid layer, and a bottom layer defined in a direction from the upper coil part 3 toward the lower electrode part 7.

To this end, in the present step, the lower electrode part 7 may be provided on a lower side of the mounting part 2 of the inner space of the reaction chamber 1, and may be electrically connected to the low frequency power supply source 8, thereby receiving low frequency power. More specifically, the lower electrode part 7 may receive low frequency power having a frequency lower than that of the upper coil part 3. For example, the low frequency power applied from the low frequency power supply source 8 to the lower electrode part 7 may be power in a range of several hundred kHz to several MHz, for example, 400 kHz or 2 MHz.

Accordingly, the inductively coupled plasma etching apparatus 100 according to the embodiment of the present invention may provide high ion energy in etching the object to be etched ob through the low frequency power. More specifically, the inductively coupled plasma etching apparatus 100 may provide high ion energy by increasing a voltage applied to the object to be etched as the low frequency power is applied to the lower electrode.

Meanwhile, the lower electrode part 7 may receive the low frequency power from the low frequency power supply source 8 to be described below, and may receive the low frequency power as a pulse.

Accordingly, in the present step, as described above, ion energy may be controlled in etching the object to be etched ob by the duty ratio of the low frequency pulse power or the pulse power.

In other words, in the present step, as described above, the radio frequency power is applied to the upper coil part 3 and the low frequency pulse power is applied to the lower electrode part 7, so that the CD value of the pattern formed by etching the object to be etched ob may be uniform as described above.

In this case, as described above, the low frequency power matching part 9 may be provided in the power supply line between the low frequency power supply source 8 and the lower electrode part 7.

Accordingly, the low frequency power matching part 9 may match impedance by minimizing an impedance difference between the output terminal of the low frequency power supply source 8 and the input terminal of the lower electrode part 7.

Hereinafter, experimental examples of the present invention will be described.

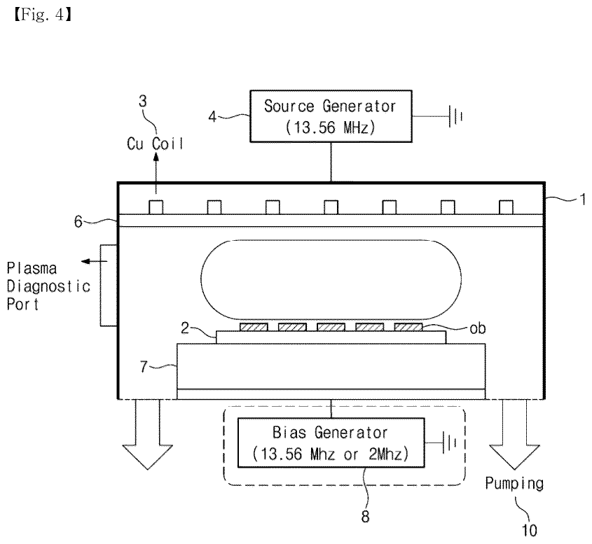

FIGS. 4 to 12 are views for explaining experimental examples of the present invention.

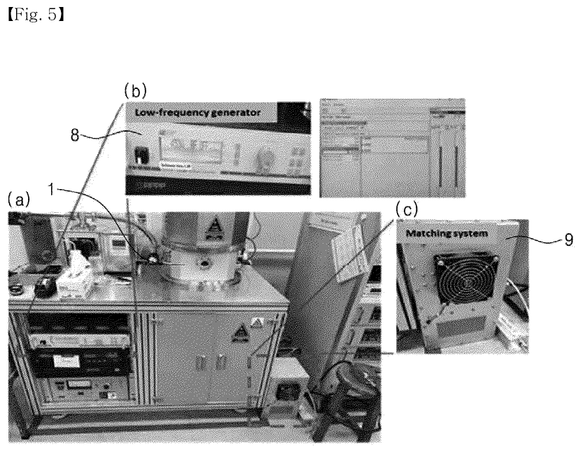

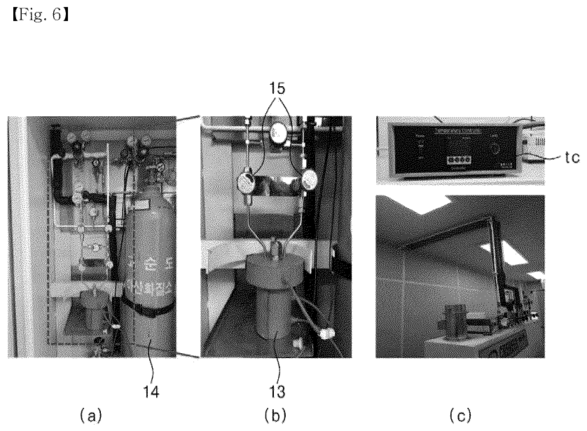

FIG. 4 illustrates a design diagram for implementing a proto-type apparatus according to experimental examples of the present invention, and FIGS. 5 and 6 illustrate an actual appearance of the proto-type apparatus according to experimental examples of the present invention.

### Etching of Object to be Etched According to Experimental Example 1

According to Experimental Example 1 of the present invention, as illustrated in FIG. 4, a Cu coil was prepared as the upper coil part 3, and radio frequency power of 13.56 MHz was applied from the radio frequency power supply source (source generator) 4 to the upper coil part (Cu coil) 3. Meanwhile, low frequency power of several hundred kHz to several MHz or lower, which is lower than the radio frequency power, was applied from the low frequency power supply source (bias generator) 8 to the lower electrode part 7 as a pulse.

As described above, this is to provide high ion energy and control ion energy in etching the object to be etched by applying the radio frequency power to the upper coil part 3 and applying the low frequency pulse power to the lower electrode part 7. More specifically, this is to provide high ion energy by applying the low frequency power to the lower electrode 7 to increase a voltage applied to the object to be etched.

In this case, an object to be etched (SiO₂), using an amorphous carbon layer as a mask, was prepared as a masking material and was disposed on the mounting part 2 of the inner space of the reaction chamber 1.

Meanwhile, the inner space of the reaction chamber 1 was pumped through the pressure adjustment part 10, and was maintained in a vacuum state.

Meanwhile, as illustrated in (c) of FIG. 5, the low frequency power matching part 9 was disposed in the power supply line between the low frequency power supply source 8 and the lower electrode part 7 illustrated in (a) and (b) of FIG. 5.

As described above, this is to match the impedance by minimizing the impedance difference between the output terminal of the low frequency power supply source 8 and the input terminal of the lower electrode part 7 by the low frequency power matching part 9.

Meanwhile, referring to (b) of FIG. 6, the heating part 13 was provided to surround the liquid source storage part 12, and the liquid source in the liquid source storage part 12 was heated through the heating part 13 to form the gas source.

Meanwhile, as illustrated in (a) of FIG. 6, the carrier gas 14 was provided in the heating part 13, and the gas source was transferred to the reaction chamber by the carrier gas 14.

In this case, in order to maintain a temperature atmosphere in which the gas source was formed in carrying the gas source to the inner space of the reaction chamber 1, the gas source supply line between the heating part 13 and the reaction chamber 1 was also wound by a heating line.

In this case, as illustrated in (c) of FIG. 6, a temperature controller tc was connected to the heating line to etch the object to be etched according to Experimental Example 1 of the present invention while monitoring a temperature of the heating line.

### Etching of Object to be Etched According to Comparative Example 1

Meanwhile, in order to compare with Experimental Example 1 of the present invention, the proto-type device according to the experimental example of the present invention was used, but the object to be etched was etched according to Comparative Example 1 by applying radio frequency power of 13.56 MHz instead of the low frequency power of several hundred kHz to several MHz to the lower electrode part.

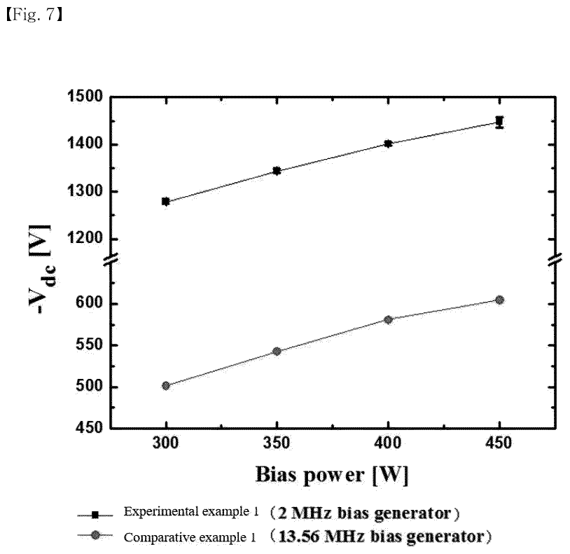

Referring to FIG. 7, a voltage according to the power applied to the lower electrode part of the present invention may be observed.

In the present invention, it can be seen that the voltage applied to the object to be etched is increased by two times or more than the voltage of the radio frequency power that has been used, for example, 13.56 MHz, by fixing the power of 50 W to the upper coil part 3 and applying the low frequency power to the lower electrode 7. It is possible to apply high ion energy using the high voltage provided through the inductively coupled plasma apparatus 100, and it is possible to form a vertical pattern of an insulating film having a pattern of a micrometer or less using the high ion energy.

Referring to FIG. 8, the pattern of the object to be etched according to Experimental Example 1 of the present invention may be observed.

According to Experimental Example 1 of the present invention, it may be observed that the pattern formed on the object to be etched has a uniform critical dimension (CD) value between a top layer, a mid layer, and a bottom layer defined in a direction from the upper coil part 3 to the lower electrode part 7.

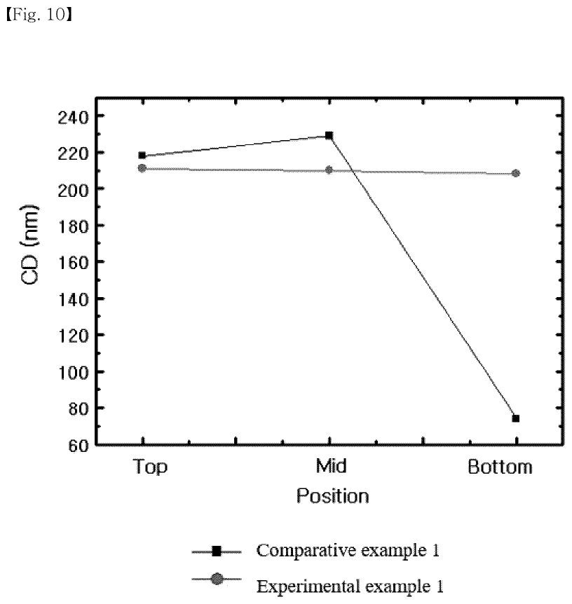

More specifically, as illustrated in FIG. 10, it can be seen that the pattern formed on the object to be etched according to Experimental Example 1 has almost the same CD between a top layer, which is defined as a layer toward the upper coil part, and a bottom layer, which is defined as a layer toward the lower electrode part.

In this case, the CD ratio between top layer and the bottom layer used herein is a value obtained by dividing the CD value of the bottom layer by the CD value of the top layer (CD value of bottom layer/CD value of top layer), and 1 may be an index. Accordingly, it may be indicated that the pattern is etched with a uniform line width over the top layer and the bottom layer as the CD ratio is equal to 1 or close to 1.

Furthermore, according to Experimental Example 1 of the present invention, it can be seen that the CD values of the mid layer and the bottom layer are the same.

Meanwhile, referring to FIG. 9, a pattern of an object to be etched according to Comparative Example 1 may be observed.

In the pattern formed on the object to be etched according to Comparative Example 1, it may be observed that the CD ratio between the top layer, the mid layer, and the bottom layer is not uniform. More specifically, as illustrated in FIG. 10, it can be seen that the pattern formed on the object to be etched according to Comparative Example 1 has a large difference in CD value between the top layer and the bottom layer.

Compared to the fact that the CD ratio value of Experimental Example 1 of the present invention described above is close to 1, the CD ratio value according to Comparative Example 1 is 0.32, and it can be seen that the CD ratio value of Experimental Example 1 of the present invention is closer to 1, which is the index described above.

This means that, according to the embodiment of the present invention, it is possible to form a pattern in which an insulating film is vertically etched to a size of a micrometer or less using high ion energy provided through the inductively coupled plasma apparatus 100.

Thus, it may be proved that anisotropy of the pattern formed by etching the object to be etched according to Experimental Example 1 of the present invention is excellent.

### Analysis of Plasma Characteristics According to Experimental Example 2-1

In Experimental Example 1 described above, a plasma was formed according to Experimental Example 2-1 of the present invention by using decafluoropentane (C₅H₂F₁₀) as a liquid source to extract plasma characteristics.

### Analysis of Plasma Characteristics According to Experimental Example 2-2

In Experimental Example 1 described above, a plasma was formed according to Experimental Example 2-2 of the present invention by using tetrafluoropropene (C₃H₂F₄) as a liquid source to extract plasma characteristics.

### Analysis of Plasma Characteristics According to Comparative Example 2

In Experimental Example 1 described above, a plasma was formed according to Comparative Example 2 by using fluoroform (CHF₃) as a conventional vapor source to extract plasma characteristics.

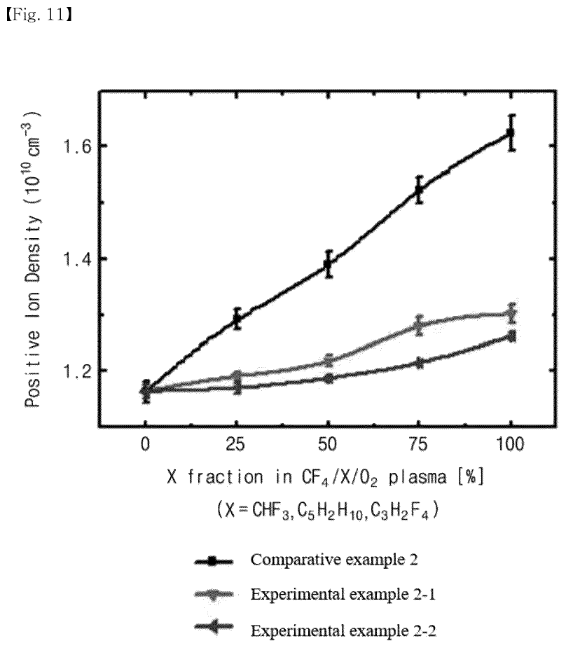

Referring to FIG. 11, an ion density according to a gas fraction of the liquid sources according to Experimental Examples 2-1 and 2-2 of the present invention and the vapor source according to Comparative Example 2 may be observed.

It can be seen that the liquid sources according to Experimental Examples 2-1 and 2-2 of the present invention have ion densities up to 1.3 (unit 10¹⁰ cm⁻³) or less even when the gas fraction is increased to 100%, whereas the vapor source (fluoroform (CHF₃)) according to Comparative Example 2 has an ion density of 1.3 (unit 10¹⁰ cm⁻³) or more when the gas fraction is increased to 25%.

Thus, as described above, it can be seen that the ion density of the liquid source of the present invention is lower than the ion density of the conventional vapor source.

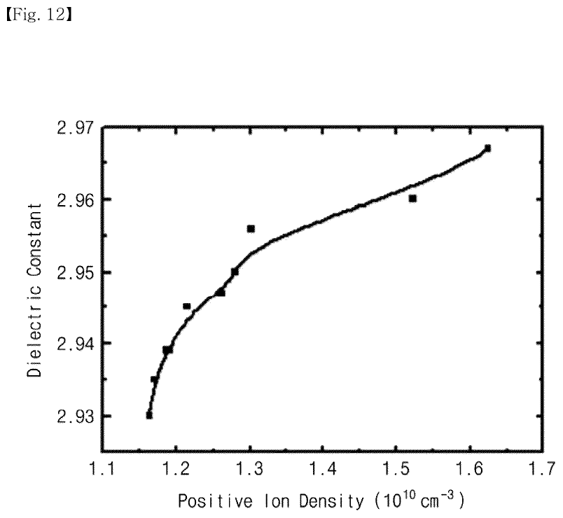

Meanwhile, referring to FIG. 12, a change in dielectric constant of the dielectric (SiOC, etc.) according to the ion density may be shown.

As described above, it can be seen that the liquid sources according to Experimental Examples 2-1 and 2-2 of the present invention have a dielectric constant of 2.955 or less with a small range of variation due to the ion density up to 1.3 (unit 10¹⁰ cm⁻³) or less even when the gas fraction is increased to 100%, whereas the liquid source of Comparative Example 2 has a dielectric constant of 2.955 or more with a large range of variation due to the increase in ion density of 1.3 (unit 10¹⁰ cm⁻³) or more.

The above-described etching characteristics of the present invention have not been implemented through the existing inductively coupled plasma apparatus. This shows that the HARC process, which was impossible by the conventional inductively coupled plasma, may be performed through the present invention. These results show that the problem of applying high power using capacitive plasma has been overcome.

Thus, according to the experimental examples of the inventive concept, it may be proved that damage to the object to be etched may be minimized even when the object to be etched (SiOC, etc.) used as an inter metal dielectric (IMD) and an inter layer dielectric (ILD) is etched as described above.

While the present invention has been described in connection with the embodiments, it is not to be limited thereto but will be defined by the appended claims. In addition, it is to be understood that those skilled in the art can substitute, change or modify the embodiments in various forms without departing from the scope and spirit of the present invention.

1. An inductively coupled plasma etching apparatus comprising:
a reaction chamber having an inner space to which a gas source is provided;
an upper coil part configured to induce an electric field into the inner space of the reaction chamber and form an inductively coupled plasma from the gas source by the electric field;
a mounting part which faces the upper coil part and on which an object to be etched by the inductively coupled plasma is disposed; and
a lower electrode part provided on a lower side of the mounting part to induce at least any one of ions and neutral active species forming the inductively coupled plasma and involved in etching toward the object to be etched disposed on the mounting part,
wherein a frequency of the lower electrode part is lower than a frequency of the upper coil part.

2. The inductively coupled plasma etching apparatus of claim 1, further comprising:
a radio frequency power supply source for applying radio frequency power to the upper coil part;
a low frequency power supply source for applying low frequency power to the lower electrode part;
a radio frequency power matching part provided in a power supply line between the radio frequency power supply source and the upper coil part; and
a low frequency power matching part provided in a power supply line between the low frequency power supply source and the lower electrode part,
wherein the low frequency power supply source applies the low frequency power to the lower electrode part as a pulse.

3. The inductively coupled plasma etching apparatus of claim 1, further comprising a gas supply unit configured to provide the gas source into the inner space of the reaction chamber,
wherein the gas supply unit includes:
a liquid source storage part configured to store a liquid source which is in a liquid state at normal temperature;
a heating part configured to surround the liquid source storage part and heat the liquid source stored in the liquid source storage part to form the gas source from the liquid source;
a carrier gas for carrying the gas source;
a flow rate adjustment part configured to adjust a flow rate of at least one of the gas source and the carrier gas; and
a gas source supply part configured to supply the gas source carried by the carrier gas into the inner space of the reaction chamber.

4. The inductively coupled plasma etching apparatus of claim 3, wherein the gas supply unit includes a gas source storage part configured to store a gas source which is in a gaseous state at normal temperature.

5. The inductively coupled plasma etching apparatus of claim 1, further comprising:
a dielectric plate disposed under the upper coil part; and
a pressure adjustment part configured to adjust a pressure of the inner space of the reaction chamber.

6. The inductively coupled plasma etching apparatus of claim 1, wherein a pattern, which is formed on the object to be etched as the object is etched,
has a critical dimension (CD) ratio between a top layer, which is defined as a layer toward the upper coil part, and a bottom layer, which is defined as a layer toward the lower electrode part, is in a range of 0.95 to 1, and
is vertically etched at a pattern size of micrometer or less in a direction from the top layer to the bottom layer.

7. An inductively coupled plasma etching method comprising:
disposing an object to be etched on a lower side of an inner space of a reaction chamber;
providing a gas source into the inner space of the reaction chamber;
inducing an electric field into the inner space of the reaction chamber by an upper coil part of the inner space of the reaction chamber, and forming an inductively coupled plasma from the gas source by the electric field; and
etching the object to be etched by inducing at least one of ions and neutral active species, which form the inductively coupled plasma and are involved in etching, toward the object to be etched by a lower electrode part facing the upper coil part,
wherein a frequency of the lower electrode part is lower than a frequency of the upper coil part.

8. The inductively coupled plasma etching method of claim 7, wherein the frequency of the lower electrode is lower than the frequency of the upper coil part, and is in a range of not less than 400 kHz and less than 13.56 MHz.

9. The inductively coupled plasma etching method of claim 7, wherein the etching of the object to be etched includes adjusting ion energy by applying low frequency power to the lower electrode part as a pulse.

10. The inductively coupled plasma etching method of claim 7, wherein the providing of the gas source includes:
storing a liquid source which is in a liquid state at normal temperature;
heating the stored liquid source to form the gas source from the liquid source;
providing a carrier gas for carrying the gas source to the gas source; and
supplying the gas source carried by the carrier gas into the inner space of the reaction chamber, and
wherein in at least one of providing of the carrier gas and supplying of the gas source into the reaction chamber, a flow rate of at least one of the gas source and the carrier gas is adjusted.
